(19) United States
(12) Patent Application Publication
(10) Pub. No.: US 2026/0068610 A1
(43) Pub. Date: Mar. 5, 2026

(54) CHIP ON FILM PACKAGE HAVING BUMPS WITH REDUCED SIZE

(71) Applicant: Novatek Microelectronics Corp., Hsinchu (TW)

(72) Inventors: Wei-Ta Chiu, New Taipei City (TW); Ling-Chieh Li, Taichung City (TW); Chia-Lun Chang, Hsinchu City (TW); CHUN-WEI CHIU, Taipei City (TW)

(73) Assignee: Novatek Microelectronics Corp., Hsinchu (TW)

(21) Appl. No.: 19/250,074

(22) Filed: Jun. 26, 2025

Related U.S. Application Data
(60) Provisional application No. 63/688,319, filed on Aug. 29, 2024.

(51) Int. Cl. H01L 21/66; G01R 31/28; H01L 23/00

(52) U.S. Cl. CPC H01L 22/30; G01R 31/2884

(57) ABSTRACT

A semiconductor chip including a plurality of first pads, a plurality of second pads, a plurality of first bumps, and a plurality of second bumps is provided. The first pads and the second pads are arranged along a direction of a long side of an active surface of the semiconductor chip. The first bumps are disposed on the first pads, and configured for a chip probe test. The second bumps are disposed on the second pads, and not for the chip probe test. A size of the first bump is larger than a size of the second bump.

### CROSS-REFERENCE TO RELATED APPLICATION

This application claims the priority benefit of U.S. provisional applications Ser. No. 63/688,319, filed on Aug. 29, 2024. The entirety of the above-mentioned patent application is hereby incorporated by reference herein and made a part of this specification.

### BACKGROUND

### Technical Field

The invention generally relates to a semiconductor device. More particularly, the invention relates to a semiconductor chip.

### Description of Related Art

Chip probe (CP) test is a critical part of the semiconductor manufacturing process, located between the wafer fabrication and chip packaging steps. CP test is the verification of the electrical characteristics and functionality of each semiconductor chip at the wafer level. During the CP test process, using probe cards, the bumps of each semiconductor chip are connected to an automated test inmate equipment (ATE), which applies predetermined test signals to check that the semiconductor chip meets preset performance criteria, such as operating voltage, current consumption, signal timing, and correct execution of specific functions.

### SUMMARY

The invention is directed to a semiconductor chip, wherein the size of the bumps configured for the chip probe test remains the same, and the size of the bumps not for the chip probe test is reduced. Since the material of the bumps is usually gold, reducing the size of the bumps reduces the production costs.

An embodiment of the invention provides a semiconductor chip including a plurality of first pads, a plurality of second pads, a plurality of first bumps, and a plurality of second bumps. The first pads and the second pads are arranged along a direction of a long side of an active surface of the semiconductor chip. The first bumps are disposed on the first pads, and configured for a chip probe test. The second bumps are disposed on the second pads, and not for the chip probe test. A size of the first bump is larger than a size of the second bump.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A and FIG. 1B are top views of a semiconductor chip according to an embodiment of the invention.

FIG. 2A is a three-dimensional view of the semiconductor chip of FIG. 1B according to an embodiment of the invention.

FIG. 2B is a three-dimensional view of the first bump and the second bump of FIG. 1B according to an embodiment of the invention.

FIG. 3 is a top view of a semiconductor chip according to another embodiment of the invention.

FIG. 4 is a top view of a semiconductor chip according to another embodiment of the invention.

FIG. 5 is schematic diagram illustrating an integrated circuit according to an embodiment of the invention.

### DESCRIPTION OF THE EMBODIMENTS

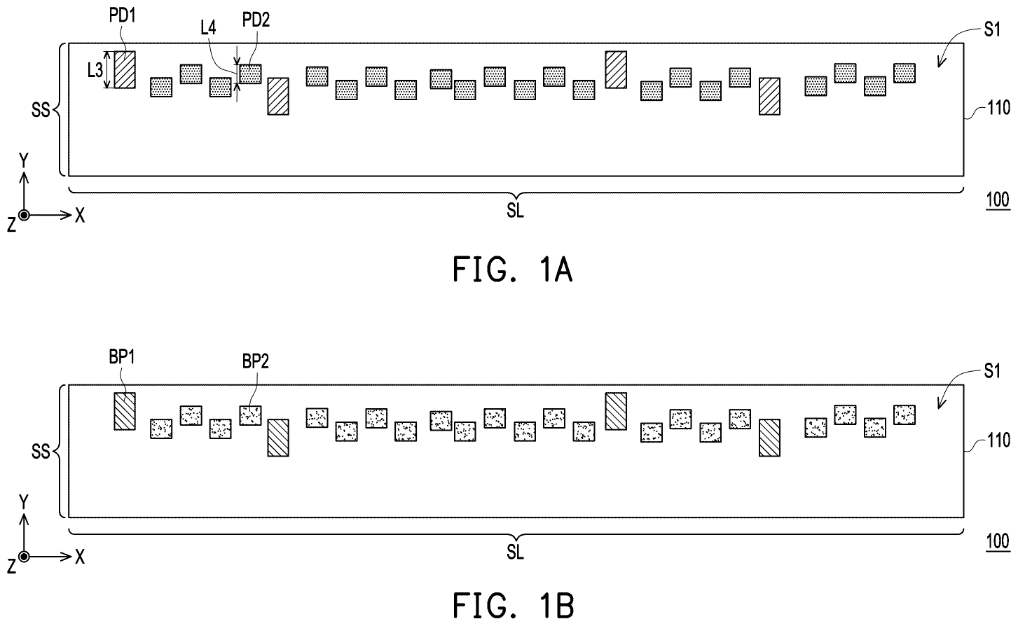

FIG. 1A and FIG. 1B are top views of a semiconductor chip according to an embodiment of the invention. Referring to FIG. 1A and FIG. 1B, the semiconductor chip 100 includes a plurality of first pads PD1, a plurality of second pads PD2, a plurality of first bumps BP1, and a plurality of second bumps BP2. The first pads PD1 and the second pads PD2 are arranged along the direction X of the long side SL of the active surface S1 of the semiconductor chip 100. The active surface S1 is a surface of the semiconductor chip 100 on which the first pads PD1 and the second pads PD2 are arranged.

The semiconductor chip 100 is capable of being mounted on a film substrate to form a chip-on-film package. Taking display driver ICs for example, the display driver ICs are usually bonded to a flexible substrate using gold bumps. The gold bumps are grown on the pads of the chip during the wafer bumping process, and in the chip probe test, the probes on the probe card contact the bumps for electrical testing.

In FIG. 1A, the size of the first pads PD1 is larger than the size of the second pads PD2. For example, the length L3 of the first pads PD1 is larger than the length L4 of the second pads PD2, wherein the length L3 of the first pads PD1 and the length L4 of the second pads PD2 are along with the direction Y of the short side SS of the active surface S1. However, the invention is not limited thereto.

FIG. 1B further illustrates the arrangement of the bumps. For the chip probe test, the arrangement of the first bumps BP1 and the second bumps BP2 corresponds to the arrangement of probes of the probe card. To be specific, the first bumps BP1 configured for the chip probe test is disposed on the first pads PD1, and the second bumps BP2 not for the chip probe test is disposed on the second pads PD2. The size of the first bump BP1 is larger than the size of the second bump BP2.

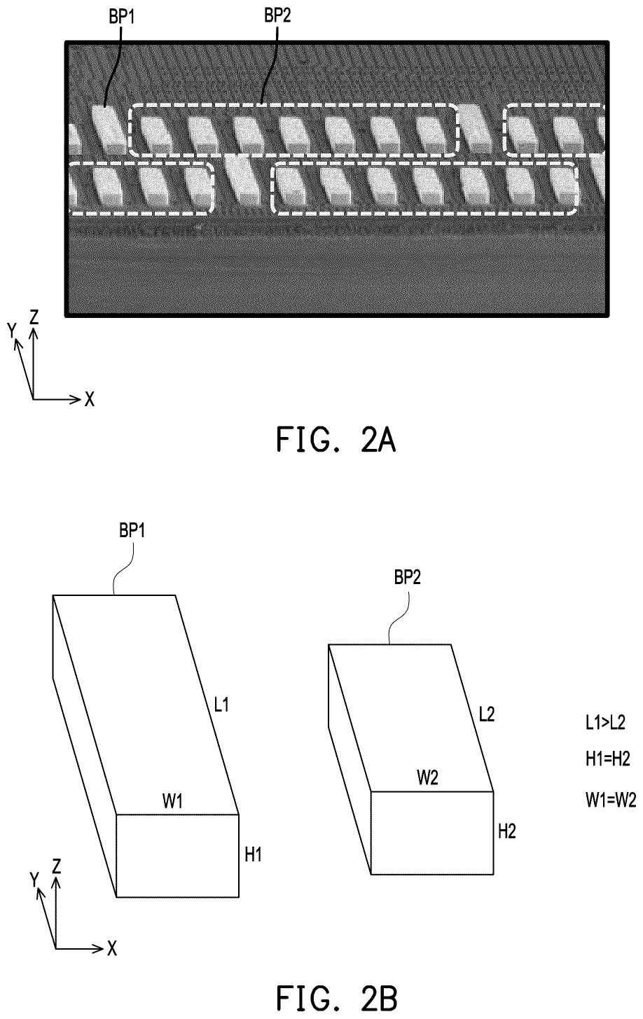

FIG. 2A is a three-dimensional view of the semiconductor chip of FIG. 1B according to an embodiment of the invention. FIG. 2B is a three-dimensional view of the first bump BP1 and the second bump BP2 of FIG. 1B according to an embodiment of the invention. Referring to FIG. 2A and FIG. 2B, in the present embodiment, the second length L2 of the second bump BP2 is smaller than the first length L1 of the first bump BP1, wherein the first length L1 of the first bump BP1 and the second length of the second bump BP2 are along with the direction Y of the short side SS of the active surface S1.

In addition, the first height H1 of the first bump BP1 is equivalent to the second height H2 of the second bump BP2. The first width W1 of the first bump BP1 is also equal to the second width W2 of the second bump BP2, wherein the first width W1 of the first bump BP1 and the second width W2 of the second bump BP2 are along with the direction X of the long side SL of the active surface S1. In another embodiment, first bump BP1 and the second bump BP2 may have different widths and/or heights, but the same lengths along with the direction Y of the short side SS.

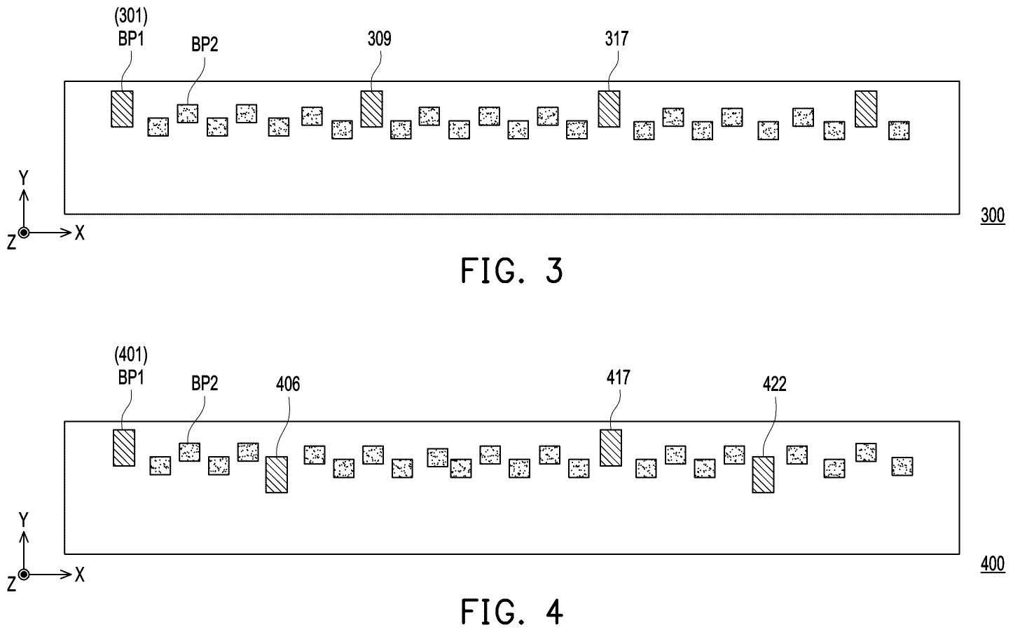

FIG. 3 is a top view of a semiconductor chip 300 according to another embodiment of the invention. Referring to FIG. 3, the same number of the second bumps BP2 is arranged between two of the first bumps BP1. For example, seven second bumps BP2 are arranged between the first bumps 301 and 309, and seven second bumps BP2 are arranged between the first bumps 309 and 317, and so on. The numbers of the second bumps BP2 are given by way of example only and are not intended to limit the invention.

FIG. 4 is a top view of a semiconductor chip 400 according to another embodiment of the invention. Referring to FIG. 4, different numbers of the second bumps BP2 are periodically arranged between two of the first bumps BP1. For example, four second bumps BP2 are arranged between the first bumps 401 and 406, and ten second bumps BP2 are arranged between the first bumps 417 and 422. That is to say, in this case, four and ten of the second bumps BP2 are periodically arranged between two of the first bumps BP1. The numbers of the second bumps BP2 are given by way of example only and are not intended to limit the invention.

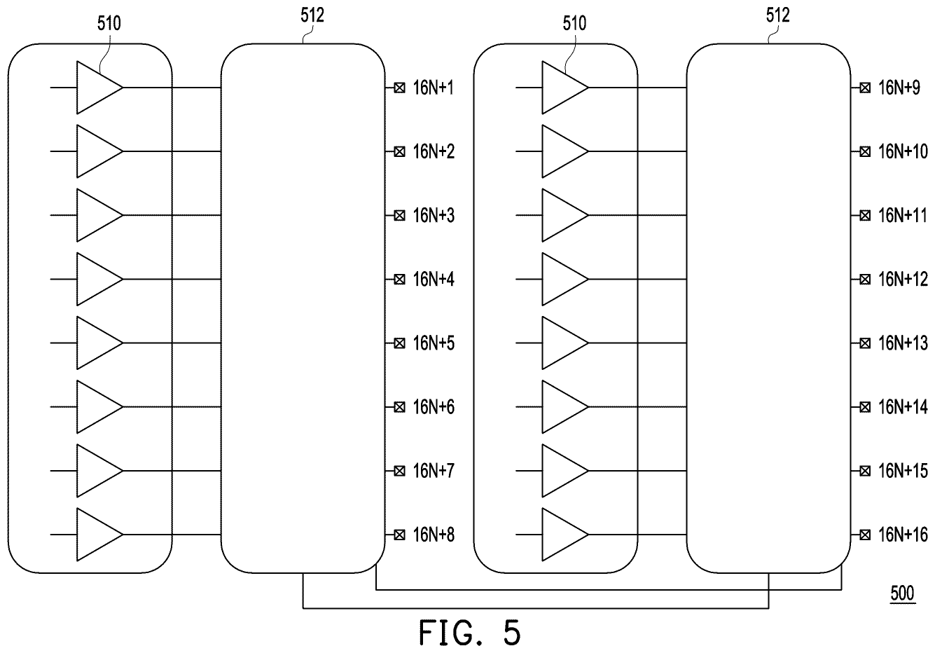

FIG. 5 is a schematic diagram illustrating an integrated circuit according to an embodiment of the invention. Referring to FIG. 1B and FIG. 5, the semiconductor chip 100 includes a display driving integrated circuit 500 as shown in FIG. 5. The integrated circuit 500 includes a plurality of display driving channels 510. The display driving channels 510 output data voltages to the display panel (not shown). The first pads PD1 and the second pads PD2 are connected to output terminals of the respective display driving channels 510.

In the present embodiment, the chip probe test is a multi-site chip probe test. In the chip probe test, by means of switching circuits 512 within the IC, hundreds or thousands of display drive channels 510 are grouped and tested in turn. The switching circuits 512 is used for the CP test. For example, each 16 display driving channels 510 is grouped for the chip probe test with two output bumps (labelled 16N+1, 16N+6) selected for probing. Other output bumps (labelled 16N+2 to 16N+5, 16N+7 to 16N+16) are not selected for probing. During the CP test, the output terminal of the 16 display driving channels 510 are one-by-one connected to the responsible one of the two probing output bumps (labelled 16N+1, 16N+6) through the switching circuits 512. Therefore, a relatively small number of bumps for the chip probe test is required.

On the other hand, In the present embodiment, the semiconductor chip 100 may be a display driver IC for driving a display panel. The first bumps BP1 and the second bumps BP1 are configured to be connected to data lines of the display panel via inner leads and outer leads disposed on the film substrate. In another embodiment, the semiconductor chip 100 may be a touch driver IC for driving a touch panel or a touch display driver IC for driving a touch display panel. In this case, the semiconductor chip 100 may include a plurality of third bumps and a plurality of fourth bumps connected to touch sensing lines of the touch panel or the touch display panel, which are made and arranged in a way similar to the first bumps BP1 and the second bumps BP2 described in the aforementioned embodiments.

In summary, in the embodiments of the invention, in the wafer bumping process for display driver ICs, the size of the bumps configured for the chip probe test remains the same, and the size of the bumps not for the chip probe test is reduced. Since the material of the bumps is usually gold, reducing the size of the bumps reduces the production costs.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor chip, comprising:
a plurality of first pads and a plurality of second pads, arranged along a direction of a long side of an active surface of the semiconductor chip;
a plurality of first bumps, disposed on the first pads, and configured for a chip probe test;
a plurality of second bumps, disposed on the second pads, and not for the chip probe test, wherein a size of the first bump is larger than a size of the second bump.

2. The semiconductor chip according to claim 1, wherein the first bumps comprise a first length, the second bump comprises a second length smaller than the first length, and the first length of the first bumps and the second length of the second bumps are along with a direction of a short side of the active surface.

3. The semiconductor chip according to claim 2, wherein the first bump comprises a first width, the second bump comprises a second width equal to the first width, and the first width of the first bumps and the second width of the second bumps are along with a direction of the long side of the active surface.

4. The semiconductor chip according to claim 3, wherein the first bump comprises a first height, the second bump comprises a second height, and the first height is equivalent to the second height.

5. The semiconductor chip according to claim 1, wherein the first pads and the second pads have the same size.

6. The semiconductor chip according to claim 1, wherein the size of the first pads is larger than the size of the second pads.

7. The semiconductor chip according to claim 1, wherein the semiconductor chip further comprises an integrated circuit, and the integrated circuit comprises:
a plurality of display driving channels, configured to output data voltages to a display panel, wherein the first pads and the second pads are connected to output terminals of the respective display driving channels.

8. The semiconductor chip according to claim 7, wherein the semiconductor chip is capable of being mounted on a film substrate to form a chip-on-film package, and the first bumps and the second bumps are configured to be connected to data lines of the display panel via inner leads and outer leads disposed on the film substrate.

9. The semiconductor chip according to claim 1, wherein the first bumps and the second bumps are connected to touch sensing lines of a touch panel or a touch display panel.

10. The semiconductor chip according to claim 1, wherein an arrangement of the first bumps and the second bumps corresponds to an arrangement of probes of a probe card.

11. The semiconductor chip according to claim 1, wherein a same number of the second bumps is arranged between two of the first bumps.

12. The semiconductor chip according to claim 1, wherein different numbers of the second bumps are periodically arranged between two of the first bumps.
